(19) United States
(12) Patent Application Publication
(10) Pub. No.: US 2015/0311263 A1
(43) Pub. Date: Oct. 29, 2015

(54) PIXEL STRUCTURE AND ELECTROLUMINESCENT DISPLAY HAVING THE SAME

(71) Applicant: INDUSTRIAL TECHNOLOGY RESEARCH INSTITUTE, Hsinchu (TW)

(72) Inventors: Kai-Sheng SHIH, Hsinchu City (TW); Yi-Shou TSAI, Taipei City (TW); Kuan-Ting CHEN, Yunlin County (TW); Yu-Chun LIN, Taipei City (TW); Wei-Ben WANG, Kaohsiung City (TW); Yu-Hsiang TSAI, Hsinchu County (TW)

(73) Assignee: INDUSTRIAL TECHNOLOGY RESEARCH INSTITUTE, Hsinchu (TW)

(21) Appl. No.: 14/452,105

(22) Filed: Aug. 5, 2014

(30) Foreign Application Priority Data
Apr. 23, 2014 (TW) 103114683

(51) Int. Cl. H01L 27/32

(52) U.S. Cl. CPC H01L 27/3218; H01L 27/3262

(57) ABSTRACT

A pixel structure and an electroluminescent display having the same are disclosed. The pixel structure comprises a first pixel and a second pixel. The first pixel and the second pixel each comprise a first sub-pixel, a second sub-pixel and a third sub-pixel. The first sub-pixel of the first pixel is adjacent to the first sub-pixel of the second pixel, the second sub-pixel of the first pixel is adjacent to the second sub-pixel of the second pixel, and the third sub-pixel of the first pixel is adjacent to the third sub-pixel of the second pixel. The first sub-pixel of the first pixel is adjacent to the first sub-pixel of the second pixel in a first direction, and the second sub-pixel of the first pixel is adjacent to the second sub-pixel of the second pixel in a second direction that is not parallel to the first direction.

This application claims the benefit of Taiwan application Serial No. 103114683 filed on Apr. 23, 2014, the disclosure of which is incorporated by reference herein in its entirety.

### BACKGROUND

1. Technical Field

The disclosure relates to a pixel structure and an electroluminescent display having the same.

2. Description of the Related Art

The resolution of displays has been improved for providing a more clear image. One approach to improve the resolution is decreasing the sizes of the pixels.

The pixels are formed in various displays by different processes. In the cases of electroluminescent displays, the pixels may be formed by evaporating organic luminescent materials using a fine metal shadow mask (FMM) in an organic light emitting diode display (OLED display), and may be formed by ink-jet printing polymer luminescent materials in a polymer light emitting diode display (PLED display).

### SUMMARY

In this disclosure, a pixel structure and an electroluminescent display having the same are provided.

According to some embodiments, the pixel structure comprises a first pixel and a second pixel. The first pixel comprises a first sub-pixel, a second sub-pixel and a third sub-pixel. The second pixel comprises a first sub-pixel, a second sub-pixel and a third sub-pixel. The first sub-pixel of the first pixel is adjacent to the first sub-pixel of the second pixel, the second sub-pixel of the first pixel is adjacent to the second sub-pixel of the second pixel, and the third sub-pixel of the first pixel is adjacent to the third sub-pixel of the second pixel. The first sub-pixel of the first pixel is adjacent to the first sub-pixel of the second pixel in a first direction, and the second sub-pixel of the first pixel is adjacent to the second sub-pixel of the second pixel in a second direction that is not parallel to the first direction.

According to some embodiments, the pixel structure comprises a first pixel and a second pixel. The first pixel comprises a first sub-pixel, a second sub-pixel and a third sub-pixel. The second pixel comprises a first sub-pixel, a second sub-pixel and a third sub-pixel. None of the first sub-pixel, the second sub-pixel and the third sub-pixel of the first pixel has a side adjacent to a side of another one of the first sub-pixel, the second sub-pixel and the third sub-pixel of the first pixel, and none of the first sub-pixel, the second sub-pixel and the third sub-pixel of the second pixel has a side adjacent to a side of another one of the first sub-pixel, the second sub-pixel and the third sub-pixel of the second pixel.

According to some embodiments, the electroluminescent display comprises a first substrate and a pixel structure disposed on the first substrate. The pixel structure comprises a first pixel and a second pixel, wherein each of the first pixel and the second pixel comprises a first sub-pixel, a second sub-pixel and a third sub-pixel. The first sub-pixel of the first pixel is adjacent to the first sub-pixel of the second pixel, the second sub-pixel of the first pixel is adjacent to the second sub-pixel of the second pixel, and the third sub-pixel of the first pixel is adjacent to the third sub-pixel of the second pixel. The first sub-pixel of the first pixel is adjacent to the first sub-pixel of the second pixel in a first direction, and the second sub-pixel of the first pixel is adjacent to the second sub-pixel of the second pixel in a second direction that is not parallel to the first direction.

According to some embodiments, the electroluminescent display comprises a first substrate and a pixel structure disposed on the first substrate. The pixel structure comprises a first pixel and a second pixel, wherein each of the first pixel and the second pixel comprises a first sub-pixel, a second sub-pixel and a third sub-pixel. None of the first sub-pixel, the second sub-pixel and the third sub-pixel of the first pixel has a side adjacent to a side of another one of the first sub-pixel, the second sub-pixel and the third sub-pixel of the first pixel, and none of the first sub-pixel, the second sub-pixel and the third sub-pixel of the second pixel has a side adjacent to a side of another one of the first sub-pixel, the second sub-pixel and the third sub-pixel of the second pixel.

### BRIEF DESCRIPTION OF THE DRAWINGS

FIGS. 1A-1D, 2A-2B, 3A-3B and 4A-4B schematically show pixel structures according to various embodiments.

FIGS. 5A-5C and 6 schematically show a process for an OLED display according to one embodiment.

FIGS. 7 and 8 schematically show a process for a PLED display according to one embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

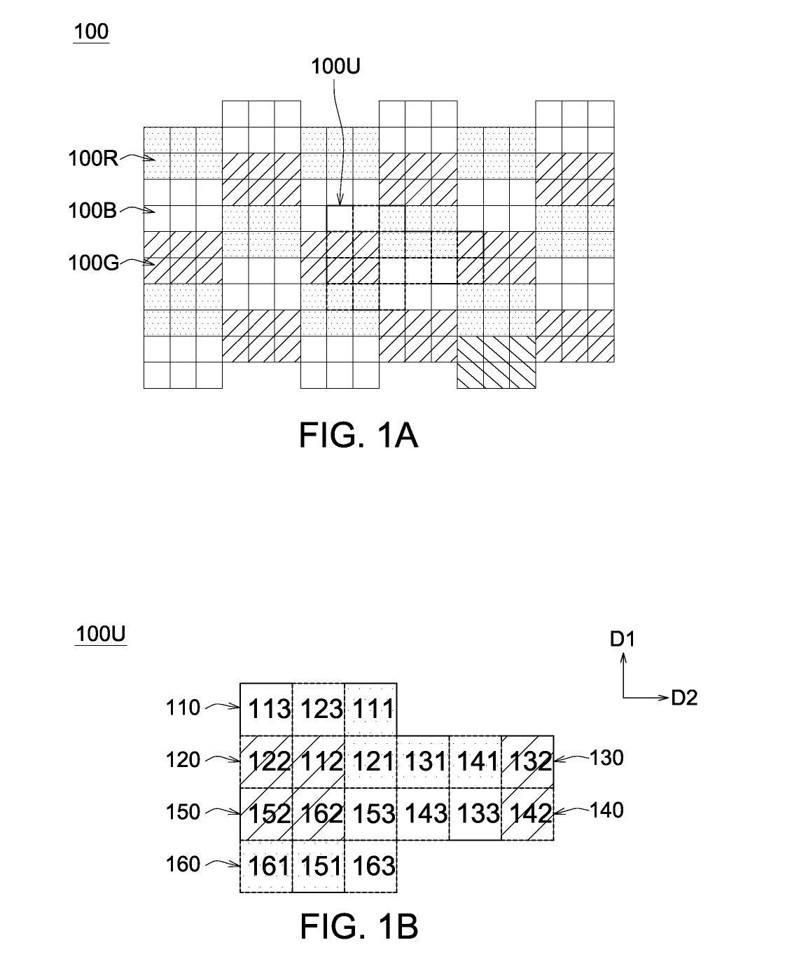

Referring to FIGS. 1A-1D, a pixel structure 100 according to one embodiment is shown. The pixel structure 100 has a plurality of first color areas, a plurality of second color areas and a plurality of third color areas, such as a plurality of red areas 100R, a plurality of green areas 100G and a plurality of blue areas 100B. The red areas 100R, the green areas 100G and the blue areas 100B have rectangle shapes.

The pixel structure 100 comprises a first pixel 110 and a second pixel 120. The first pixel 110 comprises a first sub-pixel 111, a second sub-pixel 112 and a third sub-pixel 113. The second pixel 120 comprises a first sub-pixel 121, a second sub-pixel 122 and a third sub-pixel 123. The first sub-pixel 111 of the first pixel 110 is adjacent to the first sub-pixel 121 of the second pixel 120, the second sub-pixel 112 of the first pixel 110 is adjacent to the second sub-pixel 122 of the second pixel 120, and the third sub-pixel 113 of the first pixel 110 is adjacent to the third sub-pixel 123 of the second pixel 120. The first sub-pixel 111 of the first pixel 110 is adjacent to the first sub-pixel 121 of the second pixel 120 in a first direction D1, and the second sub-pixel 112 of the first pixel 110 is adjacent to the second sub-pixel 122 of the second pixel 120 in a second direction D2 that is not parallel to the first direction D1. In this embodiment, the third sub-pixel 113 of the first pixel 110 is also adjacent to the third sub-pixel 123 of the second pixel 120 in the second direction D2. Further, none of the first sub-pixel 111, the second sub-pixel 112 and the third sub-pixel 113 of the first pixel 110 has a side adjacent to a side of another one of the first sub-pixel 111, the second sub-pixel 112 and the third sub-pixel 113 of the first pixel 110, and none of the first sub-pixel 121, the second sub-pixel 122 and the third sub-pixel 123 of the second pixel 120 has a side adjacent to a side of another one of the first sub-pixel 121, the second sub-pixel 122 and the third sub-pixel 123 of the second pixel 120. The arrangements of the first to the third sub-pixel 111-113 of the first pixel 110 and the first to the third sub-pixel 121-123 of the second pixel 120 are shown in FIGS. 1C and 1D. That is, the first pixel 110 and the second pixel 120 themselves are not symmetrical polygon shapes, but together compose a symmetrical polygon shape. This symmetrical polygon shape may comprise rectangle, parallelogram, diamond, hexagon or the like. Here, the term “adjacent to” means that two things, among all things of the type, are closest to each other, and they may directly contact to or be separated from each other. Here, the direction in the description “adjacent to . . . in a/the . . . direction” is defined as the direction perpendicular to the two adjacent sides.

The first sub-pixel 111, the second sub-pixel 112 and the third sub-pixel 113 of the first pixel 110 are sub-pixels of different colors. The first sub-pixel 121, the second sub-pixel 122 and the third sub-pixel 123 of the second pixel 120 are sub-pixels of different colors. In the embodiment of FIGS. 1A-1D, the first sub-pixel 111, the second sub-pixel 112 and the third sub-pixel 113 of the first pixel 110, as well as the first sub-pixel 121, the second sub-pixel 122 and the third sub-pixel 123 of the second pixel 120, have square shapes.

The pixel structure 100 may further comprise a third pixel 130 and a fourth pixel 140. The third pixel 130 comprises a first sub-pixel 131, a second sub-pixel 132 and a third sub-pixel 133. The fourth pixel 140 comprises a first sub-pixel 141, a second sub-pixel 142 and a third sub-pixel 143. The first sub-pixel 131 of the third pixel 130 is adjacent to the first sub-pixel 141 of the fourth pixel 140, the second sub-pixel 132 of the third pixel 130 is adjacent to the second sub-pixel 142 of the fourth pixel 140, and the third sub-pixel 133 of the third pixel 130 is adjacent to the third sub-pixel 143 of the fourth pixel 140. The first to the third sub-pixel 131-133 of the third pixel 130 and the first to the third sub-pixel 141-143 of the fourth pixel 140 are similar to the first to the third sub-pixel 111-113 of the first pixel 110 and the first to the third sub-pixel 121-123 of the second pixel 120 with different arrangements.

The pixel structure 100 may further comprise a fifth pixel 150 and a sixth pixel 160. The fifth pixel 150 comprises a first sub-pixel 151, a second sub-pixel 152 and a third sub-pixel 153. The sixth pixel 160 comprises a first sub-pixel 161, a second sub-pixel 162 and a third sub-pixel 163. The first sub-pixel 151 of the fifth pixel 150 is adjacent to the first sub-pixel 161 of the sixth pixel 160, the second sub-pixel 152 of the fifth pixel 150 is adjacent to the second sub-pixel 162 of the sixth pixel 160, and the third sub-pixel 153 of the fifth pixel 150 is adjacent to the third sub-pixel 163 of the sixth pixel 160. The first to the third sub-pixel 151-153 of the fifth pixel 150 and the first to the third sub-pixel 161-163 of the sixth pixel 160 are similar to the first to the third sub-pixel 111-113 of the first pixel 110 and the first to the third sub-pixel 121-123 of the second pixel 120, as well as the first to the third sub-pixel 131-133 of the third pixel 130 and the first to the third sub-pixel 141-143 of the fourth pixel 140, with different arrangements.

As shown in FIGS. 1A and 1B, the first sub-pixel 121 of the second pixel 120 may be adjacent to the first sub-pixel 131 of the third pixel 130, the third sub-pixel 143 of the fourth pixel 140 may be adjacent to the third sub-pixel 153 of the fifth pixel 150, and the second sub-pixel 162 of the sixth pixel 160 may be adjacent to the second sub-pixel 112 of the first pixel 110. The first pixel 110, the second pixel 120, the third pixel 130, the fourth pixel 140, the fifth pixel 150 and the sixth pixel 160 compose a repeating unit 100U of the pixel structure 100. The first sub-pixels 111, 121, 131 and 141 of one repeating unit 100U may be located at the same color area as the first sub-pixels 151 and 161 of another repeating unit 100U, for example, six red first sub-pixels are located at the same red area 100R. The second sub-pixels 112, 122, 152 and 162 of one repeating unit 100U may be located at the same color area as the second sub-pixels 132 and 142 of another repeating unit 100U, for example, six green second sub-pixels are located at the same green area 100G. The third sub-pixels 133, 143, 153 and 163 of one repeating unit 100U may be located at the same color area as the third sub-pixels 113, 123 of another repeating unit 100U, for example, six blue third sub-pixels are located at the same blue area 100B.

In the case shown in FIGS. 1A-1B, the first sub-pixels 111-161 are located at the red areas 100R, the second sub-pixels 112-162 are located at the green areas 100G, and the third sub-pixels 113-163 are located at the blue areas 100B. In other words, the first sub-pixels 111-161 are red sub-pixels, the second sub-pixels 112-162 are green sub-pixels, and the third sub-pixels 113-163 are blue sub-pixels. However, the embodiment is not limited thereto. For example, the first sub-pixels 111-161 may be green sub-pixels, the second sub-pixels 112-162 may be blue sub-pixels, and the third sub-pixels 113-163 may be red sub-pixels.

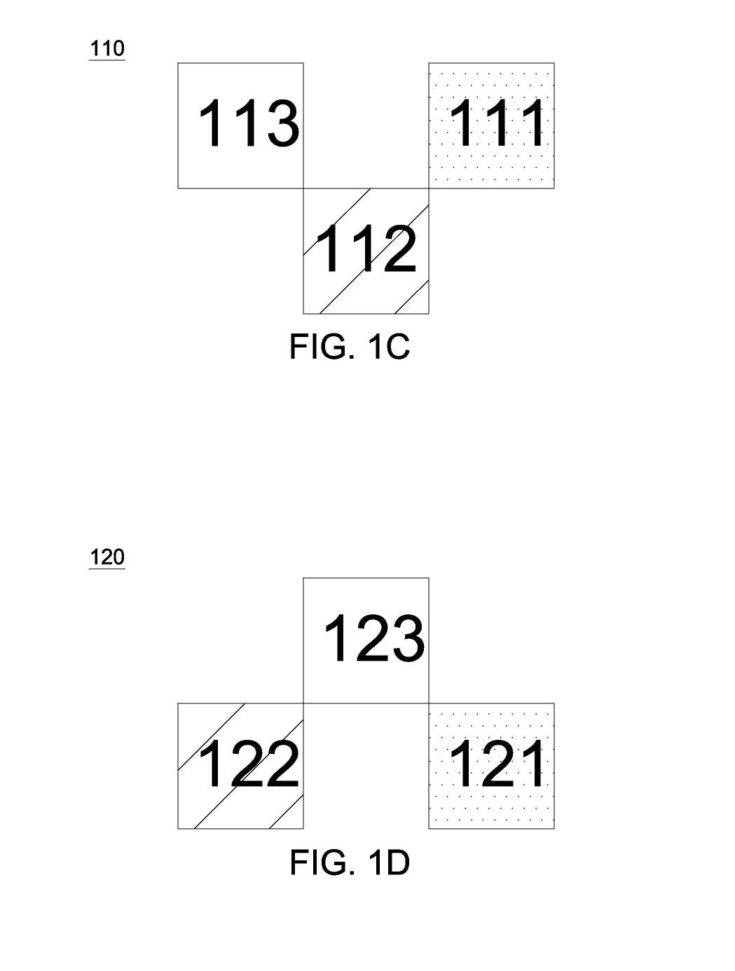

Referring to FIGS. 2A-2B, a pixel structure 200 according to one embodiment is shown. The pixel structure 200 has a plurality of first color areas, a plurality of second color areas and a plurality of third color areas, such as a plurality of red areas 200R, a plurality of green areas 200G and a plurality of blue areas 200B. The red areas 200R, the green areas 200G and the blue areas 200B have rectangle shapes. The pixel structure 200 comprises a first pixel 210 and a first sub-pixel 211, a second sub-pixel 212 and a third sub-pixel 213 thereof, a second pixel 220 and a first sub-pixel 221, a second sub-pixel 222 and a third sub-pixel 223 thereof, a third pixel 230 and a first sub-pixel 231, a second sub-pixel 232 and a third sub-pixel 233 thereof, a fourth pixel 240 and a first sub-pixel 241, a second sub-pixel 242 and a third sub-pixel 243 thereof, a fifth pixel 250 and a first sub-pixel 251, a second sub-pixel 252 and a third sub-pixel 253 thereof, a sixth pixel 260 and a first sub-pixel 261, a second sub-pixel 262 and a third sub-pixel 263 thereof, as well as a repeating unit 200U. The arrangements of these elements are similar to the corresponding elements of the pixel structure 100. The pixel structure 200 is different from the pixel structure 100 in that the first sub-pixels 211-261, the second sub-pixels 212-262 and the third sub-pixels 213-263 have rectangle shapes.

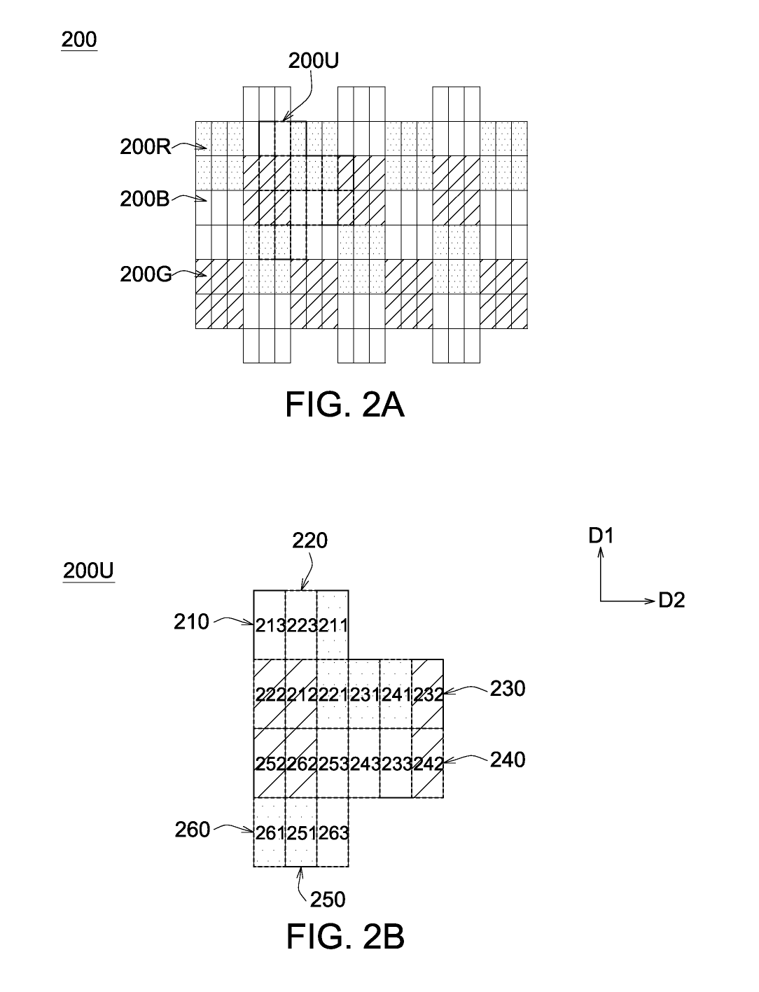

Referring to FIGS. 3A-3B, a pixel structure 300 according to one embodiment is shown. The pixel structure 300 has a plurality of first color areas, a plurality of second color areas and a plurality of third color areas, such as a plurality of red areas 300R, a plurality of green areas 300G and a plurality of blue areas 300B. The red areas 300R, the green areas 300G and the blue areas 300B have regular hexagon shapes. The pixel structure 300 comprises a first pixel 310 and a first sub-pixel 311, a second sub-pixel 312 and a third sub-pixel 313 thereof, a second pixel 320 and a first sub-pixel 321, a second sub-pixel 322 and a third sub-pixel 323 thereof, a third pixel 330 and a first sub-pixel 331, a second sub-pixel 332 and a third sub-pixel 333 thereof, a fourth pixel 340 and a first sub-pixel 341, a second sub-pixel 342 and a third sub-pixel 343 thereof, a fifth pixel 350 and a first sub-pixel 351, a second sub-pixel 352 and a third sub-pixel 353 thereof, a sixth pixel 360 and a first sub-pixel 361, a second sub-pixel 362 and a third sub-pixel 363 thereof, as well as a repeating unit 300U. The arrangements of these elements are similar to the corresponding elements of the pixel structure 100. The pixel structure 300 is different from the pixel structure 100 in that the first sub-pixels 311-361, the second sub-pixels 312-362 and the third sub-pixels 313-363 have triangle shapes, and in that the third sub-pixel 313 of the first pixel 310 is adjacent to the third sub-pixel 323 of the second pixel 320 in a third direction D3 that is not parallel to the first direction D1 and the second direction D2.

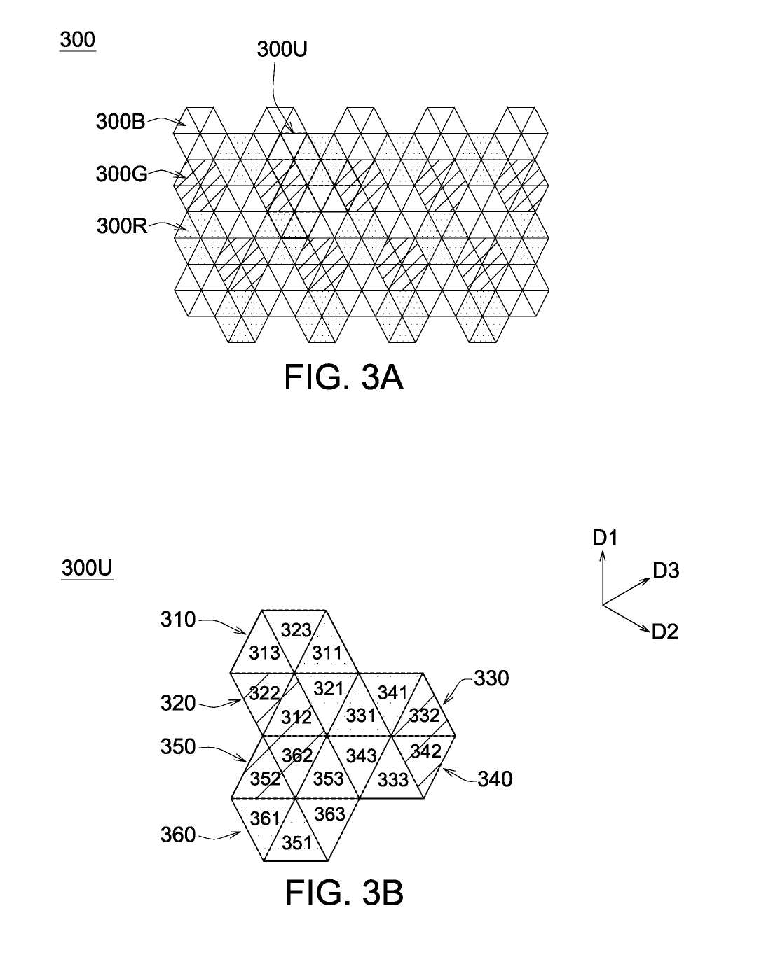

Referring to FIGS. 4A-4B, a pixel structure 400 according to one embodiment is shown. The pixel structure 400 has a plurality of first color areas, a plurality of second color areas and a plurality of third color areas, such as a plurality of red areas 400R, a plurality of green areas 400G and a plurality of blue areas 400B. The red areas 400R, the green areas 400G and the blue areas 400B have hexagon shapes. The pixel structure 400 comprises a first pixel 410 and a first sub-pixel 411, a second sub-pixel 412 and a third sub-pixel 413 thereof, a second pixel 420 and a first sub-pixel 421, a second sub-pixel 422 and a third sub-pixel 423 thereof, a third pixel 430 and a first sub-pixel 431, a second sub-pixel 432 and a third sub-pixel 433 thereof, a fourth pixel 440 and a first sub-pixel 441, a second sub-pixel 442 and a third sub-pixel 443 thereof, a fifth pixel 450 and a first sub-pixel 451, a second sub-pixel 452 and a third sub-pixel 453 thereof, a sixth pixel 460 and a first sub-pixel 461, a second sub-pixel 462 and a third sub-pixel 463 thereof, as well as a repeating unit 400U. The arrangements of these elements are similar to the corresponding elements of the pixel structure 100. The pixel structure 400 is different from the pixel structure 100 in that the first sub-pixels 411-461, the second sub-pixels 412-462 and the third sub-pixels 413-463 have trapezoid shapes, and in that the third sub-pixel 413 of the first pixel 410 is adjacent to the third sub-pixel 423 of the second pixel 420 in a third direction D3 that is not parallel to the first direction D1 and the second direction D2.

The embodiments in which the sub-pixels have square, rectangle, triangle and trapezoid shapes have been described above. However, the sub-pixels may have other shapes, such as diamond or parallelogram.

Now the description is directed to a display have the pixel structure according to any one of the embodiments described above or according to other embodiments with the same spirit and arrangement rules. Here, the disclosure is focused on the electroluminescent displays for ease of explanation.

According to some embodiments, the electroluminescent display may comprises a first substrate and a pixel structure disposed on the first substrate, wherein the pixel structure may be a pixel structure according to any one of the embodiments described above. Here, the pixel structure may be directly disposed on the first substrate, or separated from the first substrate by a distance.

The first substrate may be a TFT substrate comprising a plurality of thin film transistors (TFTs) corresponding to the sub-pixels for individually driving them. The first substrate comprises TFTs corresponding to the first sub-pixels, the second sub-pixels and the third sub-pixels of the first pixel and the second pixel. The first substrate may further comprise TFTs corresponding to the first sub-pixels, the second sub-pixels and the third sub-pixels of the third pixel, the fourth pixel, the fifth pixel and the sixth pixel. In one embodiment, each sub-pixel corresponds to at least one TFT.

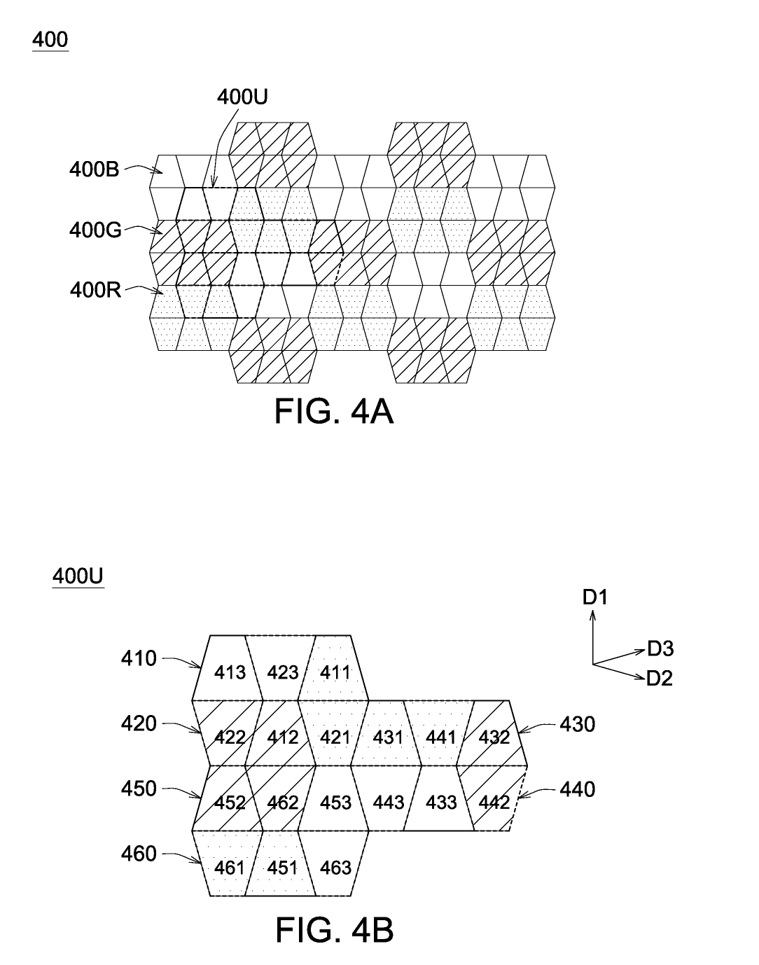

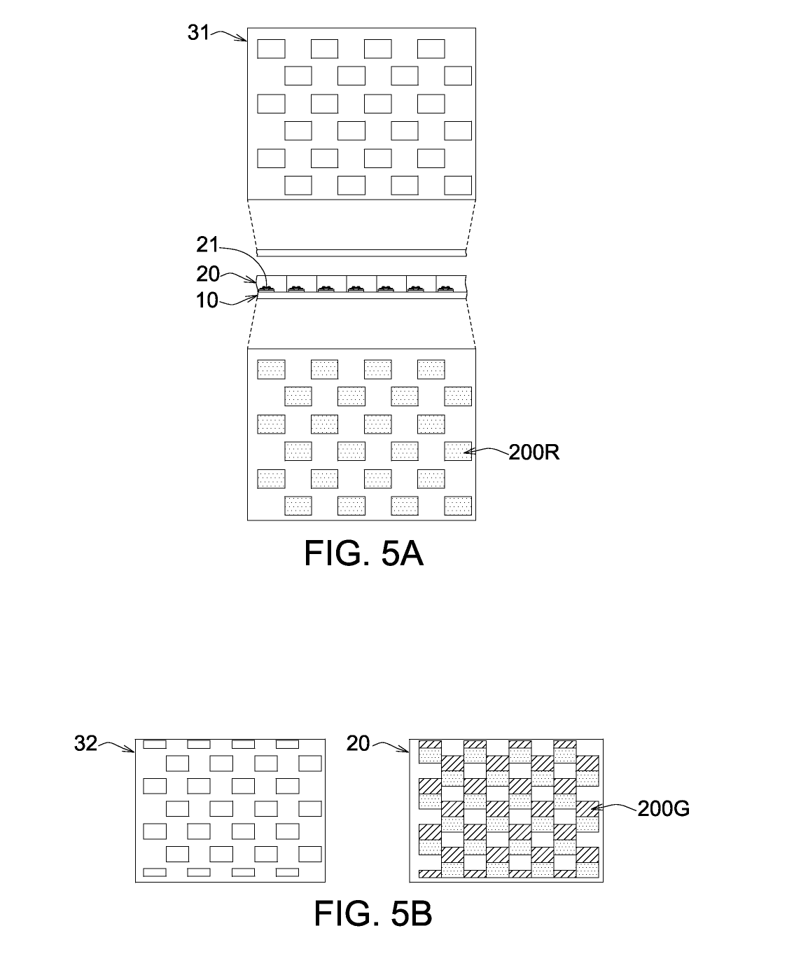

Now referring to FIGS. 5A-5C and 6, a process for an OLED display according to one embodiment is shown. For example, the OLED display comprises the pixel structure 200 as previously illustrated in FIG. 2A.

As shown in FIG. 5A, on a first substrate 10, a luminescent layer 20 may be formed. The first substrate 10 is a TFT substrate. The first substrate 10 comprises a plurality of TFTs 21 corresponding to the sub-pixels of the pixel structure to be formed. The luminescent layer 20 comprises a pixel structure 200. First, a plurality of first color areas, such as a plurality of red areas 200R, are formed on the first substrate 10 using a first shadow mask 31.

Then, as shown in FIG. 5B, a plurality of second color areas, such as a plurality of green areas 200G, are formed on the first substrate 10 using a second shadow mask 32.

Thereafter, as shown in FIG. 5C, a plurality of third color areas, such as a plurality of blue areas 200B, are formed on the first substrate 10 using a third shadow mask 33.

The luminescent layer 20 included in the pixel structure 200 is formed by the steps described above. In the luminescent layer 20, each of the red areas 200R, the green areas 200G and the blue areas 200B corresponds to at least six TFTs, so as to divide one color area to belong to six sub-pixels of the first to the sixth pixel 210-260. The six TFTs correspond to one red area 200R may define it being the first sub-pixels 211-261, the six TFTs correspond to one green area 200G may define it being the second sub-pixels 212-262, and the six TFTs correspond to one blue area 200B may define it being the third sub-pixels 213-263.

Here, since one color area may be defined as six sub-pixels using at least six TFTs, compared to the conventional OLED display, the area of each sub-pixels may be one-sixth times, thereby the resolution may be further improved. For example, the smallest size of the opening of an FMM is 42 μm*42 μm. As such, a sub-pixel of 42 μm*126 μm is formed. That is, in one area of 126 μm*126 μm, there is one pixel in the length direction (126/126), and one pixel in the width direction (126/(3*42)), the resolution is about 200*200. According to this embodiment, the 42 μm width may be shared by at most three sub-pixels, thus each of the sub-pixels thereby has one side equal to or even smaller than 14 μm. In one area of 126 μm*126 μm, there may be two pixel in the length direction (126/63), and three pixel in the width direction (126/(314)), the resolution is about 400*600.

It can be appreciated that this embodiment may further comprise other steps in the manufacturing process of OLED. For simplification, the related description is omitted herein.

Further, as shown in FIG. 6, the first substrate 10 may comprise a circuit, such as comprising a plurality of scan lines and a plurality of data lines. In FIG. 6, for simplification, only two scan lines 41 and 42 and two data lines 51 and 52 are exemplarily shown. In the cases that the display comprises a plurality of sub-pixels formed into matrix, such as the cases of the pixel structure 100 and 200, the scan lines and the data lines may be simply disposed orthogonally, and a complicate circuit design is unneeded.

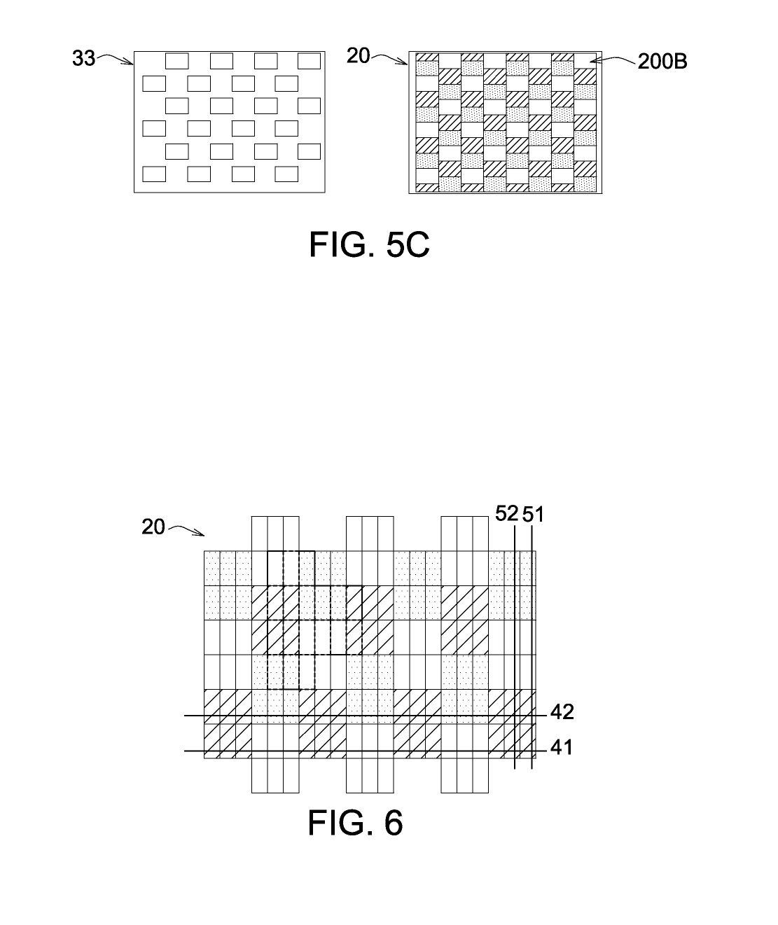

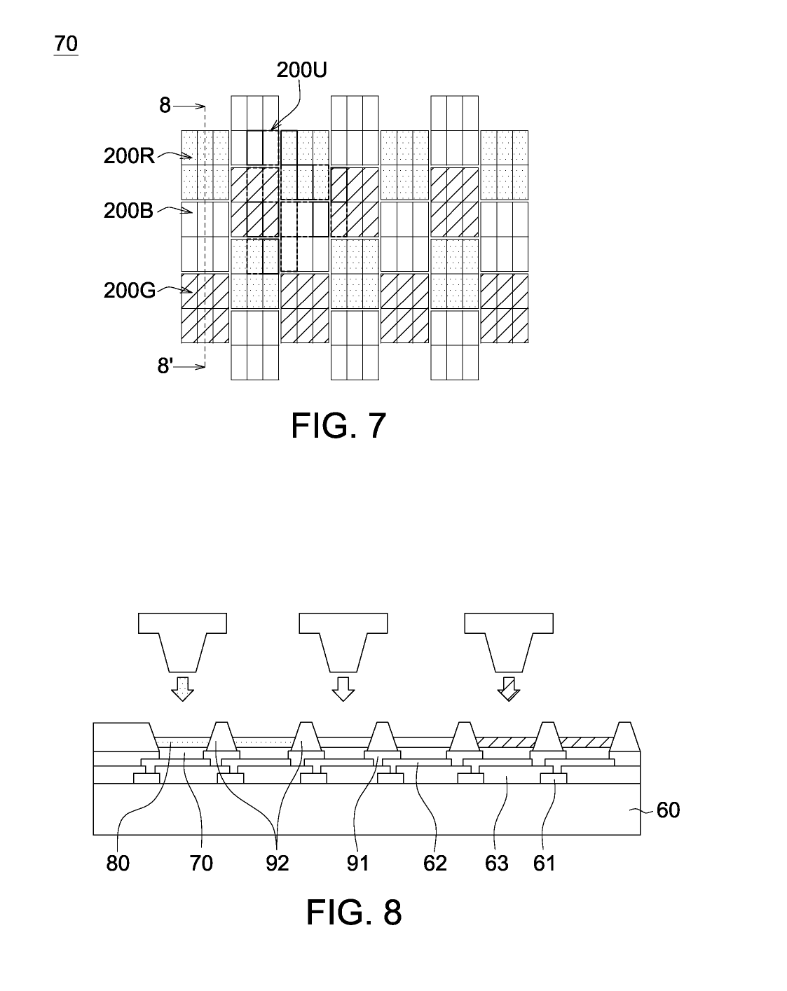

Referring to FIGS. 7 and 8, a process for a PLED display according to one embodiment is shown. For clarity, some structure and reference numerals may be omitted in the drawings. For example, the PLED display comprises the pixel structure 200, as shown in FIG. 7.

FIG. 8 shows the cross section along the cross-sectional line 8-8′ in FIG. 7. As shown in FIG. 8, on a first substrate 60, a hole transport layer 70 and a luminescent layer 80 may be sequentially formed. The first substrate 60 may comprise a TFT circuit including a plurality of TFTs 61. Each of the sub-pixels of the pixel structure to be formed corresponds to at leas one TFT 61, so as to drive the sub-pixels. The first substrate 60 may comprise an electrode layer 62 such as fabricated by ITO. The first substrate 60 may further comprise a protective layer 63 covering the TFT circuit. The hole transport layer 70 is separated by the insulating layer 91, thereby defining the areas of the sub-pixels. The luminescent layer 80 comprises the pixel structure 200. The color areas of pixel structure 200 are separated from each other by the pixel defining layer 92. As such, in the spaces surrounded by the pixel defining layer 92, polymer luminescent materials may be printed by ink-jet printing, so as to form a plurality of color areas, as shown in FIG. 8. Thereby, the luminescent layer 80 is formed.

Here, since one color area may be defined as six sub-pixels using at least six TFTs, compared to the conventional PLED display, higher resolution may be achieved without decrease of the area of the color area. In another aspect, in the cases that the resolutions are the same, a wider color area may be formed in the PLED manufactured by the method according to this embodiment. At this time, the color-mixing due to the overflow of the ink drops can be avoid. Further, the typical ink-jet printing technique can be used, thus the process can be conducted easily.

It can be appreciated that this embodiment may further comprise other steps in the manufacturing process of PLED. For simplification, the related description is omitted herein.

The embodiments in which the pixel structure 200 is included in the electroluminescent display have been described above. However, the electroluminescent display may comprise another pixel structure, such as the pixel structure 100, 300 or 400, or other pixel structure have the same spirit and arrangement rules. Further, while the above description is focused on the electroluminescent display, the pixel structure according to any one of the embodiments described above or according to other embodiments with the same spirit and arrangement rules may be used in other displays, such as being included in the color filter of a LCD.

In summary, the pixel structure in which one color area is defined as a plurality of sub-pixels by using a plurality of TFTs without the change of the area of the color area is provided. The display may comprise such a pixel structure, and thus improves the resolution. Alternatively, the process of the display may be simplified without sacrifice of resolution.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A pixel structure, comprising:
a first pixel comprising a first sub-pixel, a second sub-pixel and a third sub-pixel; and
a second pixel comprising a first sub-pixel, a second sub-pixel and a third sub-pixel;
wherein the first sub-pixel of the first pixel is adjacent to the first sub-pixel of the second pixel, the second sub-pixel of the first pixel is adjacent to the second sub-pixel of the second pixel, and the third sub-pixel of the first pixel is adjacent to the third sub-pixel of the second pixel, and
wherein the first sub-pixel of the first pixel is adjacent to the first sub-pixel of the second pixel in a first direction, and the second sub-pixel of the first pixel is adjacent to the second sub-pixel of the second pixel in a second direction that is not parallel to the first direction.

2. The pixel structure according to claim 1, wherein none of the first sub-pixel, the second sub-pixel and the third sub-pixel of the first pixel has a side adjacent to a side of another one of the first sub-pixel, the second sub-pixel and the third sub-pixel of the first pixel, and none of the first sub-pixel, the second sub-pixel and the third sub-pixel of the second pixel has a side adjacent to a side of another one of the first sub-pixel, the second sub-pixel and the third sub-pixel of the second pixel.

3. The pixel structure according to claim 1, wherein the first pixel, and the second pixel compose a symmetrical polygon.

4. The pixel structure according to claim 1, wherein the first sub-pixel, the second sub-pixel and the third sub-pixel of the first pixel are sub-pixels of different colors, the first sub-pixel, the second sub-pixel and the third sub-pixel of the second pixel are sub-pixels of different colors, and the first sub-pixel, the second sub-pixel and the third sub-pixel of the first pixel, as well as the first sub-pixel, the second sub-pixel and the third sub-pixel of the second pixel, have square, diamond, rectangle, parallelogram, triangle or trapezoid shapes.

5. The pixel structure according to claim 1, further comprising:
a third pixel comprising a first sub-pixel, a second sub-pixel and a third sub-pixel;
a fourth pixel comprising a first sub-pixel, a second sub-pixel and a third sub-pixel;
a fifth pixel comprising a first sub-pixel, a second sub-pixel and a third sub-pixel; and
a sixth pixel comprising a first sub-pixel, a second sub-pixel and a third sub-pixel;
wherein the first sub-pixel of the third pixel is adjacent to the first sub-pixel of the fourth pixel, the second sub-pixel of the third pixel is adjacent to the second sub-pixel of the fourth pixel, and the third sub-pixel of the third pixel is adjacent to the third sub-pixel of the fourth pixel; and
wherein the first sub-pixel of the fifth pixel is adjacent to the first sub-pixel of the sixth pixel, the second sub-pixel of the fifth pixel is adjacent to the second sub-pixel of the sixth pixel, and the third sub-pixel of the fifth pixel is adjacent to the third sub-pixel of the sixth pixel.

6. The pixel structure according to claim 5, wherein the first sub-pixel of the second pixel is adjacent to the first sub-pixel of the third pixel, the third sub-pixel of the fourth pixel is adjacent to the third sub-pixel of the fifth pixel, and the second sub-pixel of the sixth pixel is adjacent to the second sub-pixel of the first pixel.

7. The pixel structure according to claim 5, wherein the first pixel, the second pixel, the third pixel, the fourth pixel, the fifth pixel and the sixth pixel compose a repeating unit of the pixel structure.

8. An electroluminescent display, comprising:
a first substrate; and
a pixel structure according to claim 1 disposed on the first substrate.

9. The electroluminescent display according to claim 8, wherein the first substrate is a TFT substrate comprising a plurality of thin film transistors (TFTs) corresponding to the first sub-pixel, the second sub-pixel and the third sub-pixel of the first pixel as well as the first sub-pixel, the second sub-pixel and the third sub-pixel of the second pixel.

10. The electroluminescent display according to claim 8, being an OLED display or a PLED display.

11. A pixel structure, comprising:
a first pixel comprising a first sub-pixel, a second sub-pixel and a third sub-pixel; and
a second pixel comprising a first sub-pixel, a second sub-pixel and a third sub-pixel;
wherein none of the first sub-pixel, the second sub-pixel and the third sub-pixel of the first pixel has a side adjacent to a side of another one of the first sub-pixel, the second sub-pixel and the third sub-pixel of the first pixel, and none of the first sub-pixel, the second sub-pixel and the third sub-pixel of the second pixel has a side adjacent to a side of another one of the first sub-pixel, the second sub-pixel and the third sub-pixel of the second pixel.

12. The pixel structure according to claim 11, wherein the first pixel, and the second pixel compose a symmetrical polygon

13. The pixel structure according to claim 11, wherein the first sub-pixel, the second sub-pixel and the third sub-pixel of the first pixel are sub-pixels of different colors, the first sub-pixel, the second sub-pixel and the third sub-pixel of the second pixel are sub-pixels of different colors, and the first sub-pixel, the second sub-pixel and the third sub-pixel of the first pixel, as well as the first sub-pixel, the second sub-pixel and the third sub-pixel of the second pixel, have square, diamond, rectangle, parallelogram, triangle or trapezoid shapes.

14. The pixel structure according to claim 11, wherein the first sub-pixel of the first pixel is adjacent to the first sub-pixel of the second pixel, the second sub-pixel of the first pixel is adjacent to the second sub-pixel of the second pixel, and the third sub-pixel of the first pixel is adjacent to the third sub-pixel of the second pixel.

15. The pixel structure according to claim 14, further comprising:
a third pixel comprising a first sub-pixel, a second sub-pixel and a third sub-pixel;
a fourth pixel comprising a first sub-pixel, a second sub-pixel and a third sub-pixel;
a fifth pixel comprising a first sub-pixel, a second sub-pixel and a third sub-pixel; and
a sixth pixel comprising a first sub-pixel, a second sub-pixel and a third sub-pixel;
wherein the first sub-pixel of the third pixel is adjacent to the first sub-pixel of the fourth pixel, the second sub-pixel of the third pixel is adjacent to the second sub-pixel of the fourth pixel, and the third sub-pixel of the third pixel is adjacent to the third sub-pixel of the fourth pixel; and
wherein the first sub-pixel of the fifth pixel is adjacent to the first sub-pixel of the sixth pixel, the second sub-pixel of the fifth pixel is adjacent to the second sub-pixel of the sixth pixel, and the third sub-pixel of the fifth pixel is adjacent to the third sub-pixel of the sixth pixel.

16. The pixel structure according to claim 15, wherein the first sub-pixel of the second pixel is adjacent to the first sub-pixel of the third pixel, the third sub-pixel of the fourth pixel is adjacent to the third sub-pixel of the fifth pixel, and the second sub-pixel of the sixth pixel is adjacent to the second sub-pixel of the first pixel.

17. The pixel structure according to claim 15, wherein the first pixel, the second pixel, the third pixel, the fourth pixel, the fifth pixel and the sixth pixel compose a repeating unit of the pixel structure.

18. An electroluminescent display, comprising:
a first substrate; and
a pixel structure according to claim 11 disposed on the first substrate.

19. The electroluminescent display according to claim 18, wherein the first substrate is a TFT substrate comprising a plurality of thin film transistors (TFTs) corresponding to the first sub-pixel, the second sub-pixel and the third sub-pixel of the first pixel as well as the first sub-pixel, the second sub-pixel and the third sub-pixel of the second pixel.

20. The electroluminescent display according to claim 18, being an OLED display or a PLED display.
